(19) United States
(12) Patent Application Publication
(10) Pub. No.: US 2005/0139987 A1
(43) Pub. Date: Jun. 30, 2005

(54) Semiconductor integrated circuit device

(75) Inventors: Yasuyuki Okada, Osaka (JP); Hiroyuki Miyazaki, Kyoto (JP); Masumi Nobata, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/986,318

(22) Filed: Nov. 12, 2004

(30) Foreign Application Priority Data
Nov. 12, 2003 (JP) P. 2003-382878

(51) Int. Cl. H01L 23/12

(52) U.S. Cl. 257/700; 257/774

(57) ABSTRACT

A semiconductor integrated circuit device comprises: a semiconductor integrated circuit chip mounted on a semiconductor base, the semiconductor integrated circuit chip having a plurality of circuit systems mounted being separated and driven by different electric power source systems and also having at least one electrostatic protection circuit; and an outer connecting terminal 5 connected to the circuit systems of the semiconductor integrated circuit chip via a wiring member 4 having at least one wiring layer, wherein electric power source lines and ground lines of the plurality of circuit systems of the semiconductor integrated circuit chip 1 are respectively commonly connected on a conductive plane 43, which is provided in the wiring member, via an electrostatic protection circuit 2.

### BACKGROUND OF THE INVENTION

1. Field of the Invention

The present invention relates to a semiconductor integrated circuit device. More particularly, the present invention relates to an insertion structure of inserting the electrostatic protection circuit.

2. Description of the Related Art

In general, in the case of LSI of the flip-chip system, a probing pad is arranged in the periphery of a chip, and LSI peripheral circuit elements such as an input and output circuit cell, an electric power supply cell for an input and output circuit to supply an electric power source voltage to the input and output circuit and an electric power supply cell for LSI inner logic circuit to supply an electric power source voltage to LSI inner logic circuit are arranged at predetermined intervals in the inside region. The cell region of the LSI inner logic circuit is arranged in the inside region of LSI peripheral circuit elements.

Further, on a surface of the chip, a rearrangement wiring for connecting the terminal pad with LSI is arranged. Concerning the electric power source line to supply an electric power source voltage for driving these circuit elements, an electric power source line for LSI peripheral circuit arranged in an upper portion of LSI peripheral circuit element is provided, and an electric power source line for LSI inner logic circuit arranged in the periphery of LSI inner logic circuit is provided. These electric power source lines are arranged being electrically separate from each other. In this case, a package including a ball grid array (BGA), which is formed in the stiffener, is used for the flip-chip package.

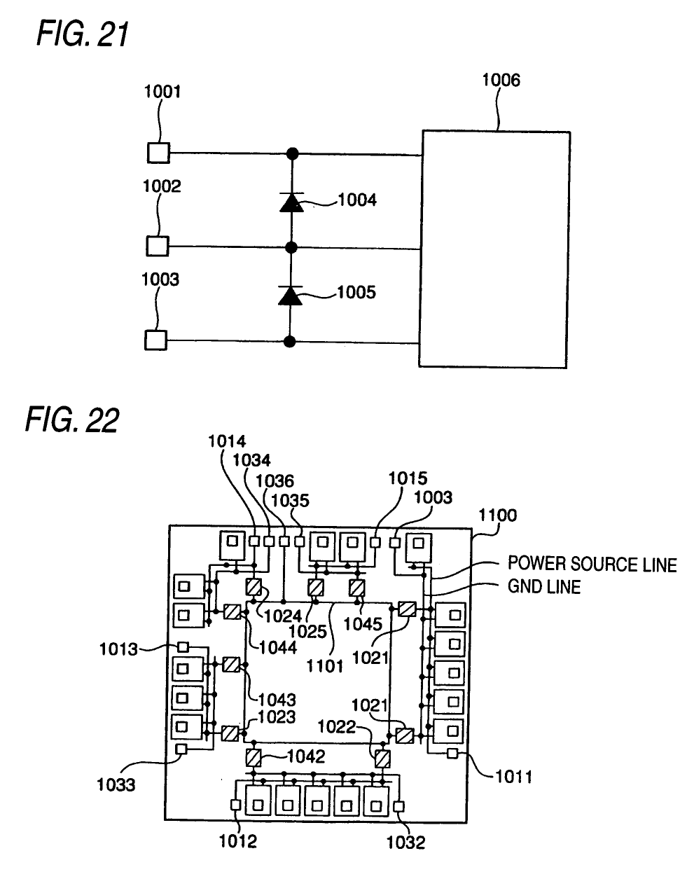

In this connection, in this semiconductor integrated circuit device, as an electrostatic protection circuit shown in FIG. 21, in which the diode 1004 is connected between the signal terminal 1002 and the electric power source terminal 1001 and the diode 1005 is connected between the signal terminal 1002 and the ground (GND) terminal 1003.

Due to the above constitution, when an electric potential is generated by static electricity between the signal terminal 1002 and the electric power source terminal 1001, in the case where the electric potential of the signal terminal 1002 is high, an electric charge is released to the electric power source terminal 1001 in the normal direction of the diode 1004. In the case where the electric potential of the signal terminal 1002 is low, the electric charge is released to the signal terminal 1002 by the yielding phenomenon in the reverse direction of the diode 1004. In this way, damage of the inner circuit 1006 caused by static electricity can be prevented.

On the other hand, when an electric potential is generated by static electricity between the signal terminal 1002 and GND terminal 1003, in the case where the electric potential of the signal terminal 1002 is low, the electric charge is released to the signal terminal 1002 in the normal direction of the diode 1005. In the case where the electric potential of the signal terminal 1002 is high, the electric charge is released to GND terminal 1003 by the yielding phenomenon in the reverse direction of the diode 5. Therefore, damage of the inner circuit 1006 caused by static electricity can be prevented.

When an electric potential is generated by static electricity between the electric power source terminal 1001 and GND terminal 1003, in the case where the electric potential of the electric power source terminal 1001 is low, the electric charge is released to the electric power source terminal 1001 in the normal direction of the diodes 1004, 1005. In the case where the electric potential of the electric power source terminal 1001 is high, the electric charge is released to GND terminal 1003 by the yielding phenomenon in the reverse direction of the diodes 1004, 1005. Therefore, damage of the inner circuit 1006 caused by static electricity can be prevented.

In the above circumstances, in the case of LSI on which analog and digital elements are mixedly mounted, when the analogue and digital elements have an electric power source terminal and GND terminal in common, it becomes impossible to obtain a desired characteristic due the influence of noise generated by the common impedance of the wiring and the bonding wire. Therefore, in order to obtain the desired characteristic, a method is adopted in which the electric power source system of the analogue elements and that of the digital elements are separate from each other. For the above reasons, in order to prevent the occurrence of damage of the elements caused by static electricity between the different electric power source systems, electrostatic protection circuits are inserted between all the electric power source systems.

However, in this semiconductor integrated circuit device, when the number of the separation of the electric power source systems is increased, it is necessary to insert a protection circuit between all the electric power source systems. When the number of the electric power source systems is represented by N, the number of the protection circuits becomes 2N(N−1). Therefore, this method is disadvantageous in that the number of the protection circuits is greatly increased and the area of the chip is increased.

Therefore, the following method is proposed. As illustrated in FIG. 22, in the semiconductor chip 1100, the common bus 1101 is provided. The electrostatic protection circuits 1021, 1022, 1023, 1024, 1025 are connected between the electric power sources 1011, 1012, 1013, 1014, 1015 and the common bus 1101. The electrostatic protection circuits 1041, 1042, 1043, 1044, 1045 are connected between GND circuits 1003, 1032, 1033, 1034, 1035 and the common bus 1101. In this way, the number of the electrostatic protection circuits 1021 can be reduced. In these electrostatic protection circuits 1021, 1022, 1023, 1024, 1025, 1041, 1042, 10423, 1044, 1045, the anode terminal 1051 of the diode is connected to the common bus, and the cathode terminal 1052 is connected to the electric power source terminal or GND terminal. The common bus 1101 is connected to GND terminal 1036, the electric potential of which is the minimum. Concerning this technique, refer to JP-A-8-148650.

However, when the common bus is formed, the wiring is restricted, which causes an increase in the area occupied by the pattern. Further, when a rearrangement wiring is made by a multilayer structure, the wiring length is longer, which causes an increase in the impedance and the driving speed is deteriorated.

As described above, according to the conventional semiconductor integrated circuit device, the following problems may be encountered. When the bit width of data is extended as a method of transferring data at high speed, the number of the input and output circuit cells is increased. Therefore, the number of the electrostatic protection circuits, which are necessary for the electric power source supply cells for the input and output circuit to supply electric power to the input and output circuit cells, is increased. In order to solve the above problems, when the electrostatic protection circuits are connected in common so as to reduce the number of the electrostatic protection circuits, it becomes necessary to compose a common bus, however, the formation of the common bus is limited, which is a big problem when the semiconductor integrated circuit device is downsized and highly integrated.

### SUMMARY OF THE INVENTION

The present invention has been accomplished in view of the above circumstances. It is an object of the present invention to provide a semiconductor integrated circuit device, the degree of freedom of designing the chip of which is high, capable of being downsized and highly integrated.

Therefore, the present invention provides a semiconductor integrated circuit device comprising: a semiconductor integrated circuit chip mounted on a semiconductor base, the semiconductor integrated circuit chip having a plurality of circuit systems mounted being separated and driven by different electric power source systems; and an outer connecting terminal connected to the circuit systems of the semiconductor integrated circuit chip via a wiring member having at least one wiring layer, wherein electric power source lines of the plurality of circuit systems of the semiconductor integrated circuit chip are commonly connected on an electrically conductive plane, which is provided in the wiring member, via an electrostatic protection circuit.

In the above constitution, by the common connection of the circuit systems, the electrostatic protection circuits such as diodes are respectively arranged between the electric power source line and the ground line. Further, this common connection is realized not in the semiconductor integrated circuit chip but on the conductive plane provided in the wiring member. Therefore, the chip area is not extended, and the connection can be accomplished at a low impedance. Further, as compared with the case in which the ground is directly connected on the semiconductor integrated chip, the transmission of noise into the chip can be prevented. Accordingly, the operation can be conducted at high speed, and the semiconductor integrated circuit device can be downsized and highly integrated. Further, since the conductive plane for forming the common bus is formed outside the semiconductor integrated circuit chip, the degree of freedom of designing the semiconductor integrated circuit chip can be enhanced. In this connection, it is preferable that the electrostatic protection circuit such as a diode is arranged between the signal terminal and the electric power source line and between the electric power source line and the ground line. It is also preferable that all the circuit systems are commonly connected. However, all the circuit systems are not necessarily commonly connected but a plurality of circuit systems may be commonly connected.

The present invention includes a semiconductor integrated circuit device in which the electrostatic protection circuit is formed on a surface of the chip.

Due to the above constitution, since the electrostatic protection circuit is integrated on the semiconductor chip, the connection can be easily made.

The present invention includes a semiconductor integrated circuit device in which the conductive plane is connected to the ground potential.

Due to the above constitution, an electric charge can be easily released by the protection circuit. Therefore, the occurrence of noise can be reduced.

The present invention includes a semiconductor integrated circuit device in which the conductive plane is connected to the electric power source potential.

Due to the above constitution, the connection to the protection circuit can be easily made, and further the length of the electric power source wiring can be reduced or made equal. Therefore, the occurrence of a voltage drop can be prevented.

The present invention includes a semiconductor integrated circuit device in which the conductive plane is divided into a plurality of regions on the same layer and connected being divided into electric power source potentials different for each region. However, on the semiconductor integrated circuit chip, the different electric power sources are connected via the protection circuits.

The present invention includes a semiconductor integrated circuit device in which the conductive plane is divided into a plurality of regions on the same plane and includes a region connected to the electric power source potential and a region connected to the ground potential.

Due to the above constitution, one conductive layer is provided with an electric power source plane and a ground plane. Therefore, in the connection to the electrostatic protection circuit, the degree of freedom of the connection can be enhanced.

The present invention includes a semiconductor integrated circuit device in which the conductive plane is comprised of a plurality of conductive planes which are provided on both sides of an insulating layer and at least one of conductive planes is connected to the ground potential or the electric power source potential.

Due to the above constitution, the degree of freedom of the connection is enhanced. Therefore, the wiring can be easily laid in the semiconductor integrated circuit chip.

The present invention includes a semiconductor integrated circuit device in which the conductive plane is provided on the wiring base substrate and electrically connected to the semiconductor integrated circuit chip via a through-hole.

The present invention includes a semiconductor integrated circuit device in which the conductive plane is formed on the substantially entire surface of the wiring substrate.

Due to the above constitution, the entire surface of the base substrate can be effectively utilized and the conductive plane can be formed in such a manner that the substantially entire surface except for the region, in which the through-hole is formed, can be covered. Therefore, the resistance can be reduced and the wiring can be easily laid.

The present invention includes a semiconductor integrated circuit device in which the conductive plane is a conductive ring.

Due to the above constitution, a connecting portion of connecting to the electric power source line or the ground line can be arranged at a position distant from the outer circumference by a predetermined distance, and the length of the wiring can be made equal.

The present invention includes a semiconductor integrated circuit device in which the conductive plane composes one layer of the multilayer wiring base substrate. The present invention includes a semiconductor integrated circuit device in which the outer connecting terminal is a terminal for mounting on the surface which is led out onto a lower face of the resin package.

The present invention includes a semiconductor integrated circuit device in which the outer connecting terminal is a ball grid array or a pin grid array.

The present invention includes a semiconductor integrated circuit device of the CSP type.

In some cases, the semiconductor integrated circuit device includes DRAM.

In the semiconductor integrated circuit device, malfunction might be caused by a voltage drop of the electric power source voltage. Therefore, it is necessary to prevent the electric power source wiring from being laid round in the device. According to the present invention, since the electric power source line can be commonly connected via the conductive plane, the laying-round of the electric power source line can be minimized. Accordingly, it is possible to provide a semiconductor integrated circuit device, the IR drop of which is small, without increasing the chip area.

It is preferable that the semiconductor integrated circuit device is LSI of the flip-chip type having a rearrangement wiring on the surface, capable of being connected to the wiring substrate while the face is being set downward.

The present invention includes a semiconductor integrated circuit in which the electrostatic protection circuit is arranged on the wiring member.

Due to the above constitution, the diode may be composed of an integrated circuit by utilizing a vacant region. Therefore, an area occupied by the chip can be reduced, and further the noise can be reduced.

The present invention includes a semiconductor integrated circuit in which the electrostatic protection circuit is comprised of parts of the chip mounted on the conductive plane.

Due to the above constitution, it is possible to reduce the area occupied by the chip. In addition to that, the semiconductor integrated circuit can be easily manufactured.

As explained above, according to the semiconductor integrated circuit device of the present invention, the electric power sources of the same voltage, which are on the conductive plane provided not in the semiconductor integrated circuit chip but in the wiring member, or the ground are connected in common. Due to the foregoing, the electrostatic protection circuit provided between the electric power source line and the ground line can be used in common. Therefore, the connection can be accomplished at low impedance without increasing the chip area. Since the noise can be prevented from being transmitted into the chip, the device can be operated at high speed, and the semiconductor integrated circuit device can be downsized and highly integrated. Since the conductive plane for forming the common bus is formed outside the semiconductor integrated circuit chip, the degree of freedom of designing the semiconductor integrated circuit chip can be enhanced.

### BRIEF DESCRIPTION OF THE RELATED ART

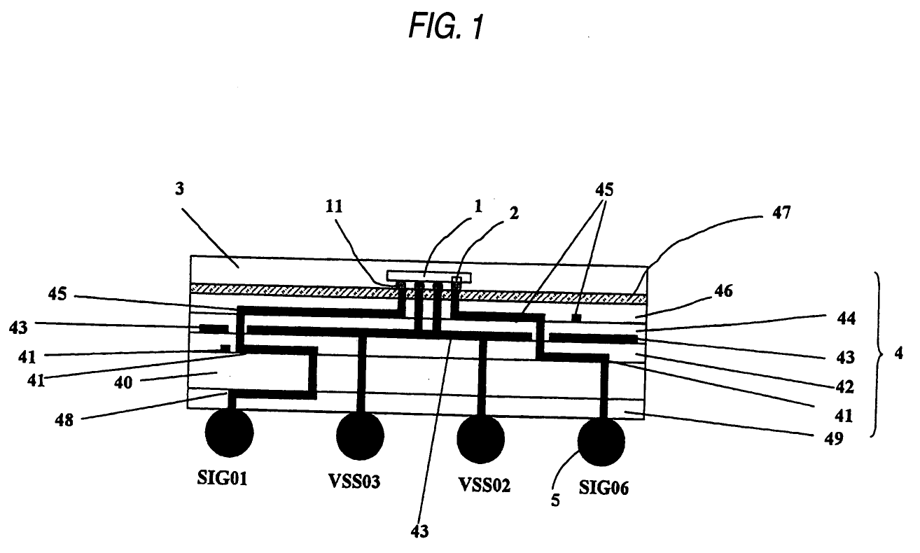

FIG. 1 is a sectional view showing a semiconductor integrated circuit device of the first embodiment.

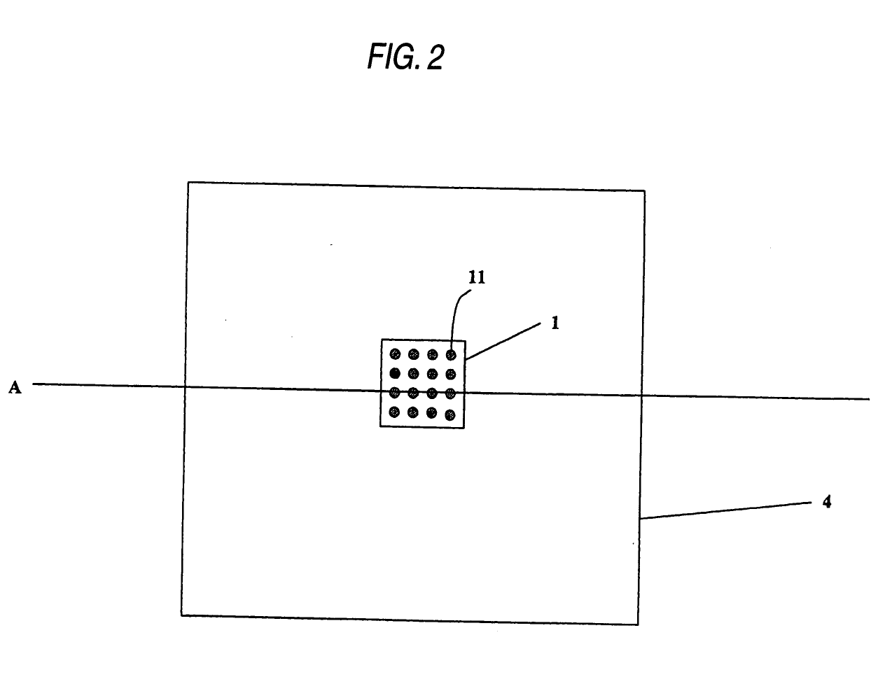

FIG. 2 is a view showing a semiconductor chip and package of the first embodiment.

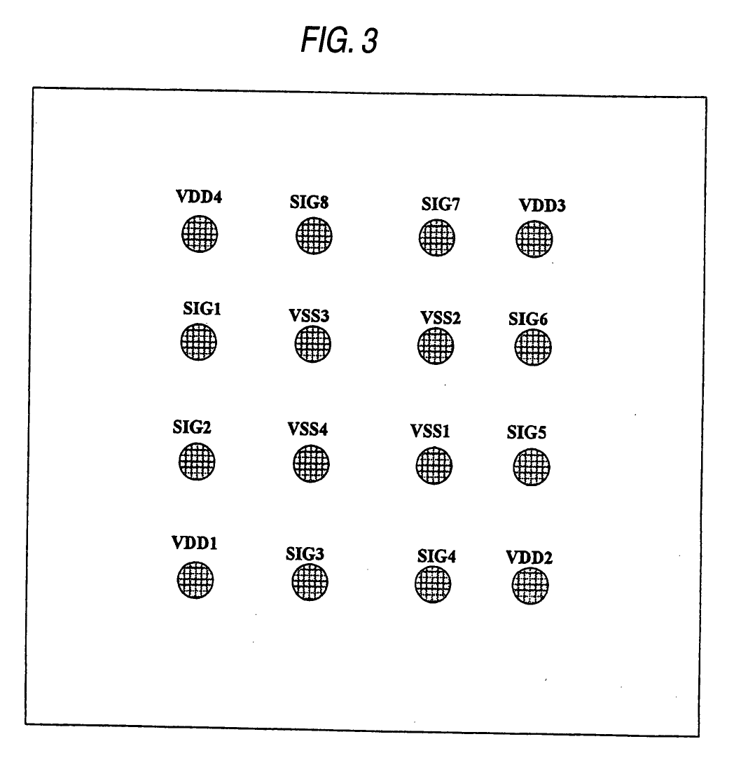

FIG. 3 is a reverse side view showing a semiconductor chip of the first embodiment.

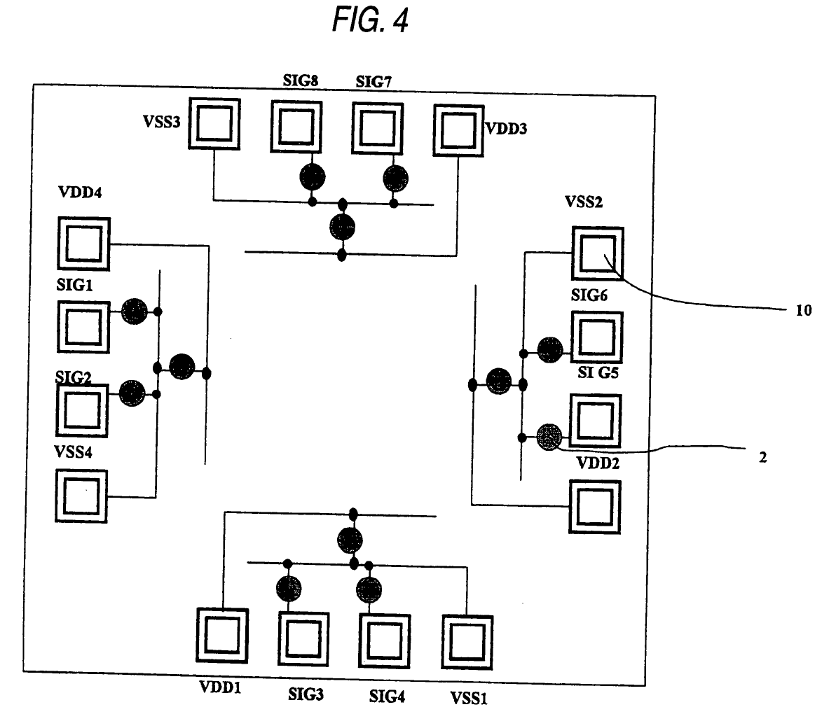

FIG. 4 is an enlarged view of a semiconductor chip of the first embodiment.

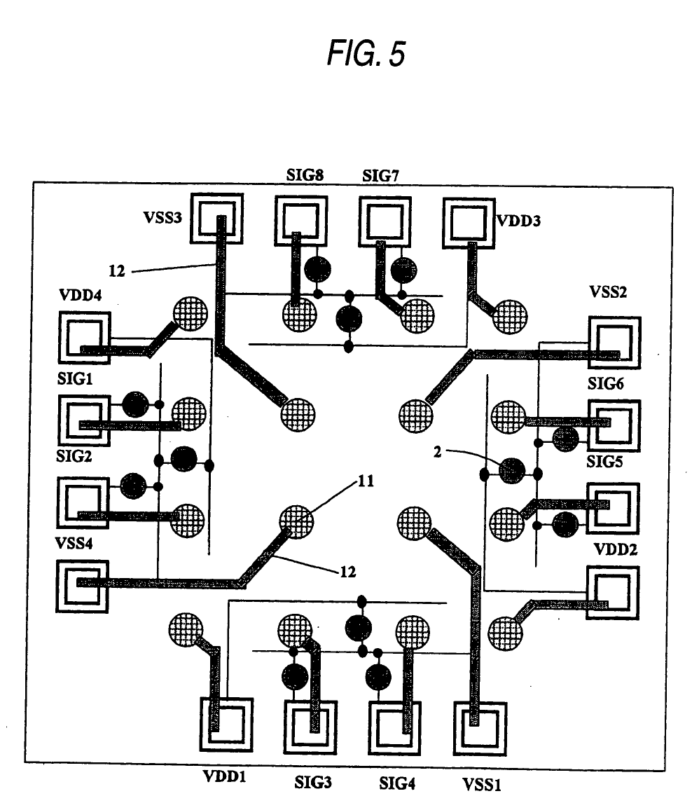

FIG. 5 is a view showing a surface after the completion of rearrangement wiring of a semiconductor chip of the first embodiment.

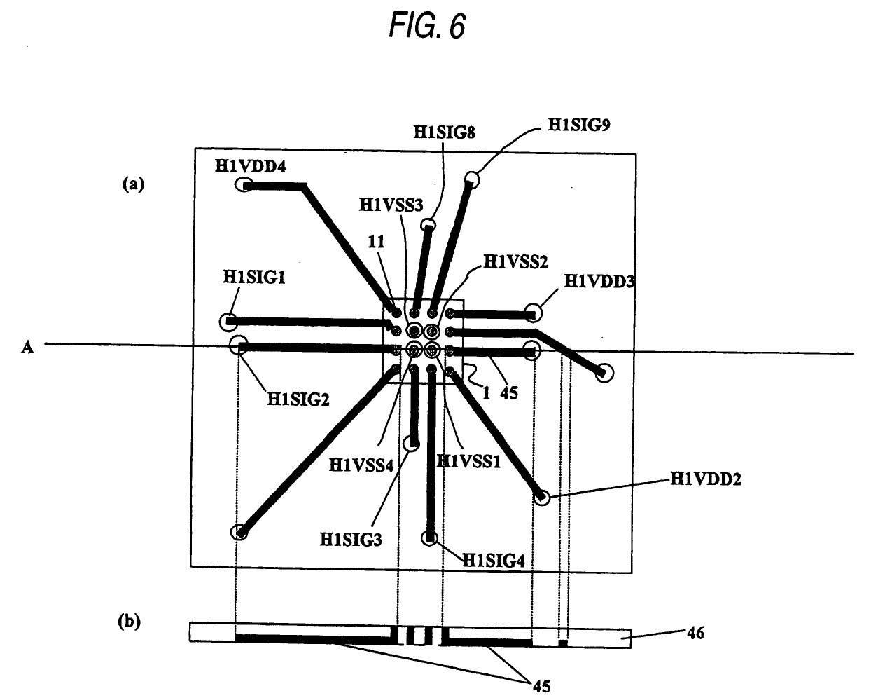

FIGS. 6(a) and 6(b) are respectively a plan view and a sectional view showing the first layer wiring of a semiconductor integrated circuit device.

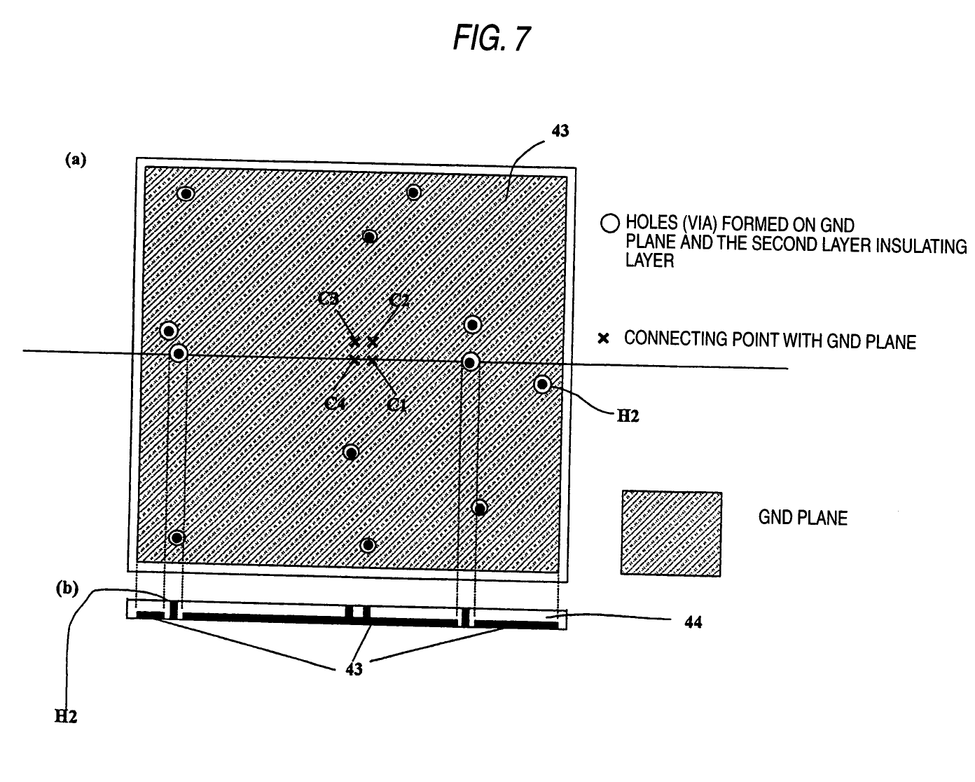

FIGS. 7(a) and 7(b) are respectively a plan view and a sectional view showing the second layer wiring of a semiconductor integrated circuit device.

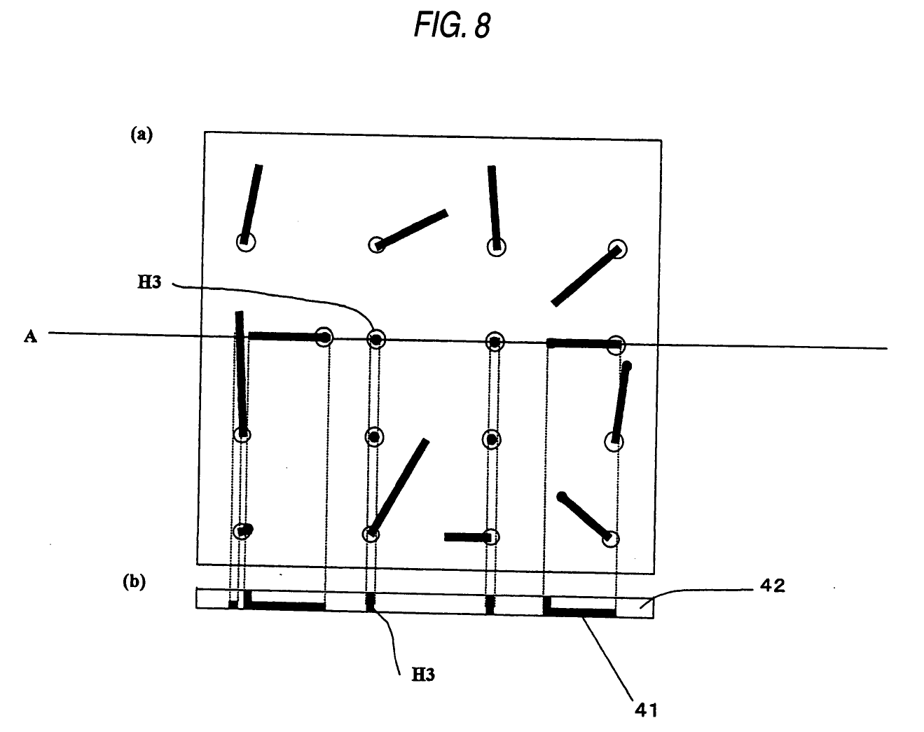

FIGS. 8(a) and 8(b) are respectively a plan view and a sectional view showing the third layer wiring of a semiconductor integrated circuit device.

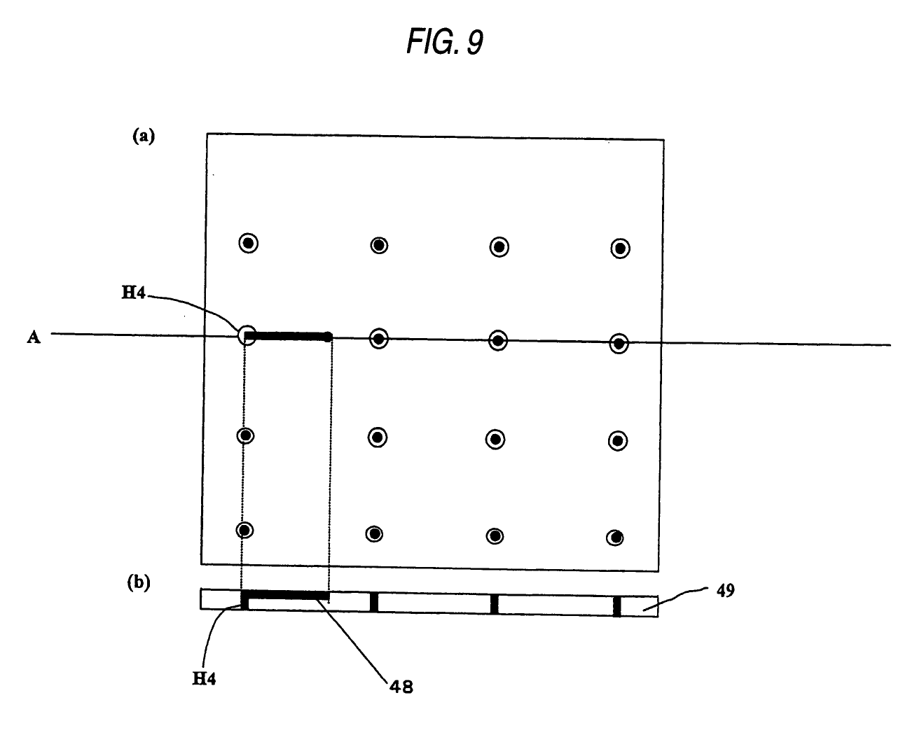

FIGS. 9(a) and 9(b) are respectively a plan view and a sectional view showing the fourth layer wiring of a semiconductor integrated circuit device.

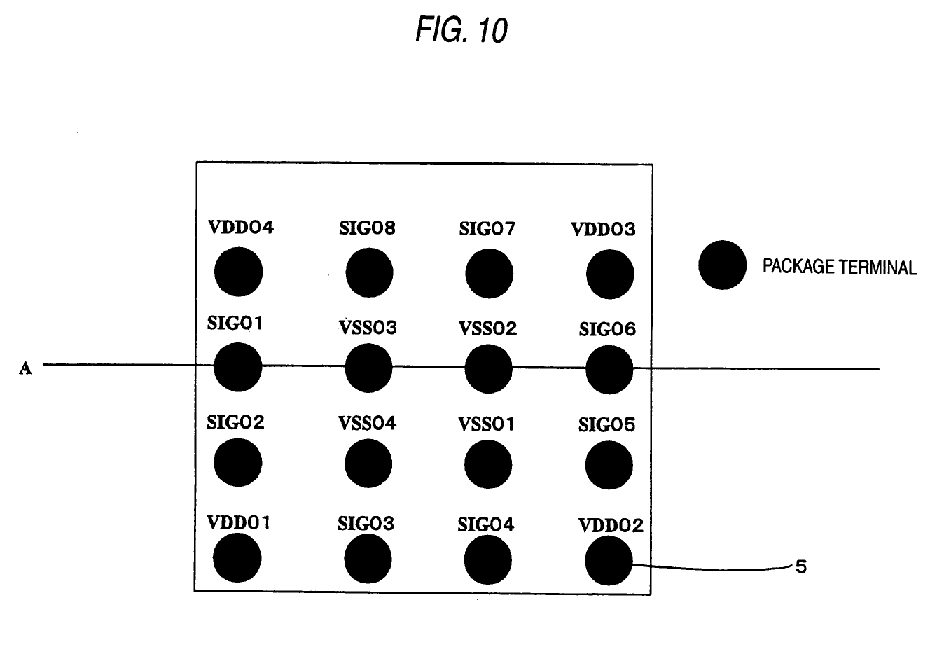

FIG. 10 is a reverse side view of the semiconductor integrated circuit device of the first embodiment after the completion of sealing.

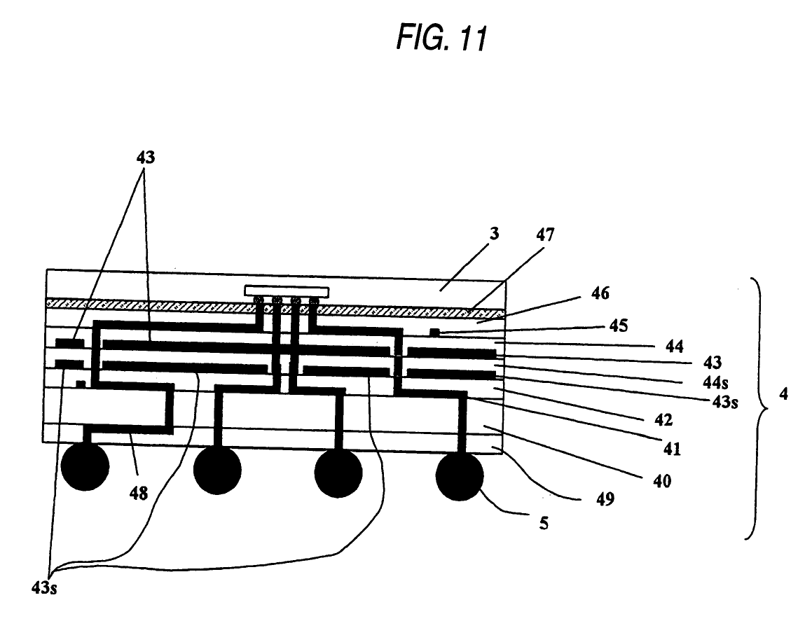

FIG. 11 is a sectional view of the semiconductor integrated circuit device of the second embodiment.

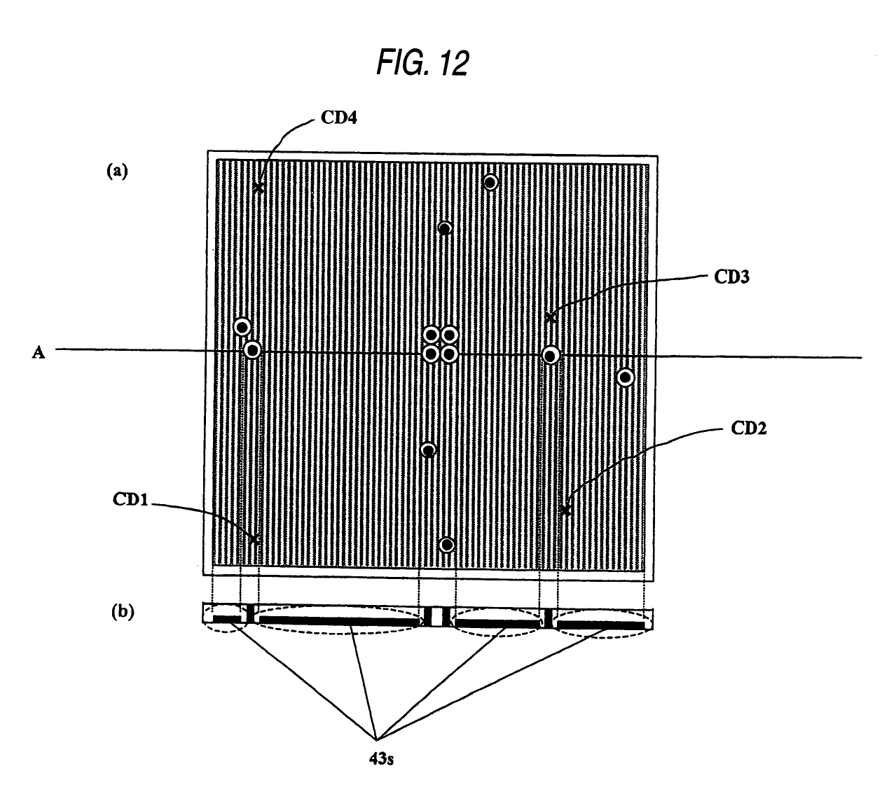

FIGS. 12(a) and 12(b) are respectively a plan view and a sectional view showing the third layer wiring of the semiconductor integrated circuit device of the second embodiment.

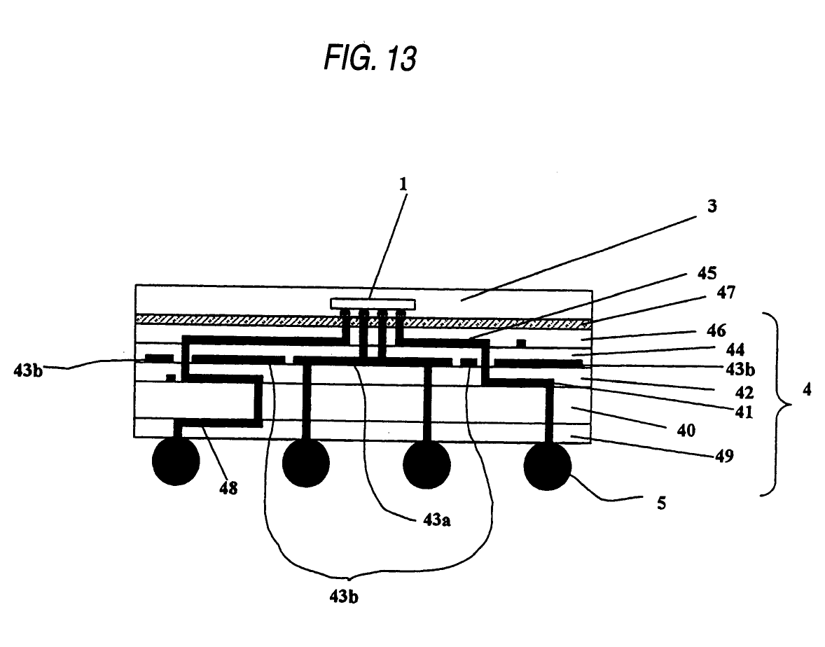

FIG. 13 is a sectional view of the semiconductor integrated circuit device of the third embodiment.

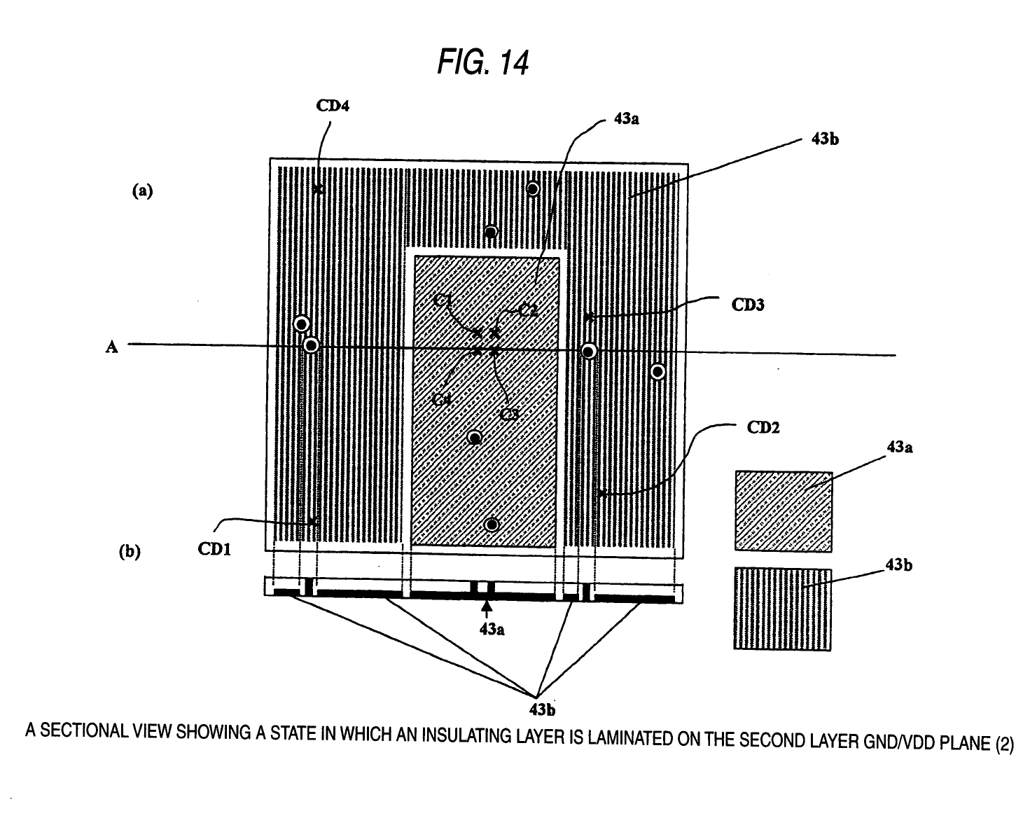

FIGS. 14(a) and 14(b) are respectively a plan view and a sectional view showing the second layer wiring of the semiconductor integrated circuit device of the third embodiment.

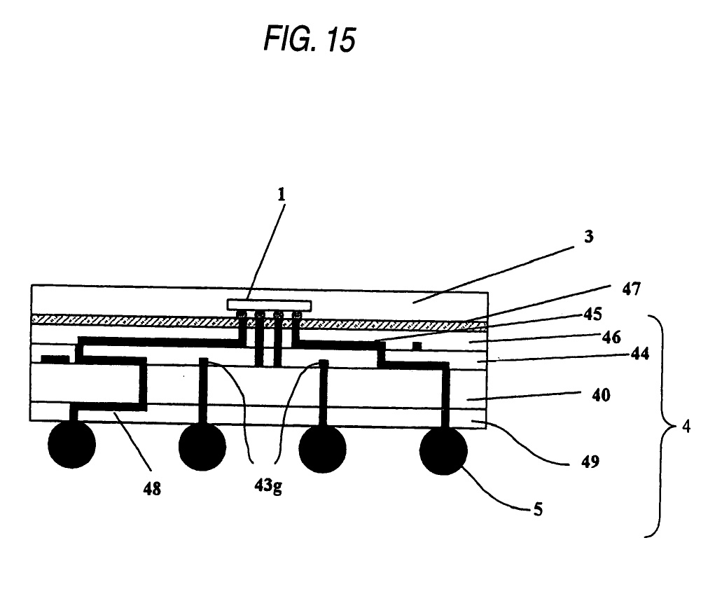

FIG. 15 is a sectional view of the semiconductor integrated circuit device of the fourth embodiment.

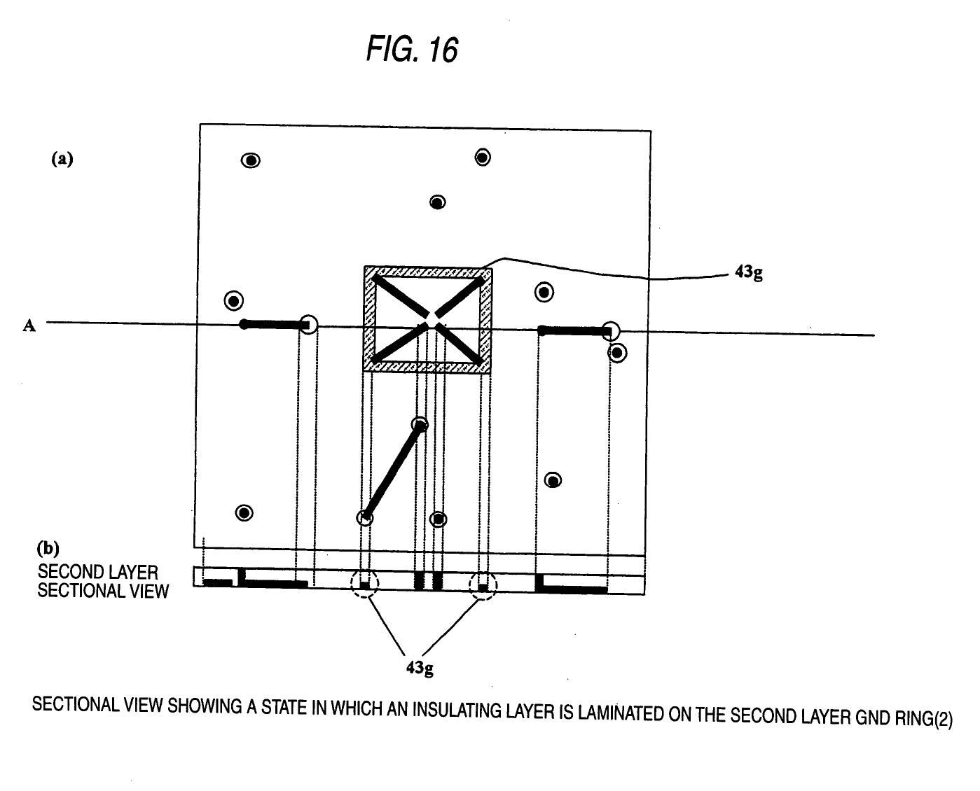

FIGS. 16(a) and 16(b) are respectively a plan view and a sectional view showing the second layer wiring of the semiconductor integrated circuit device of the fourth embodiment.

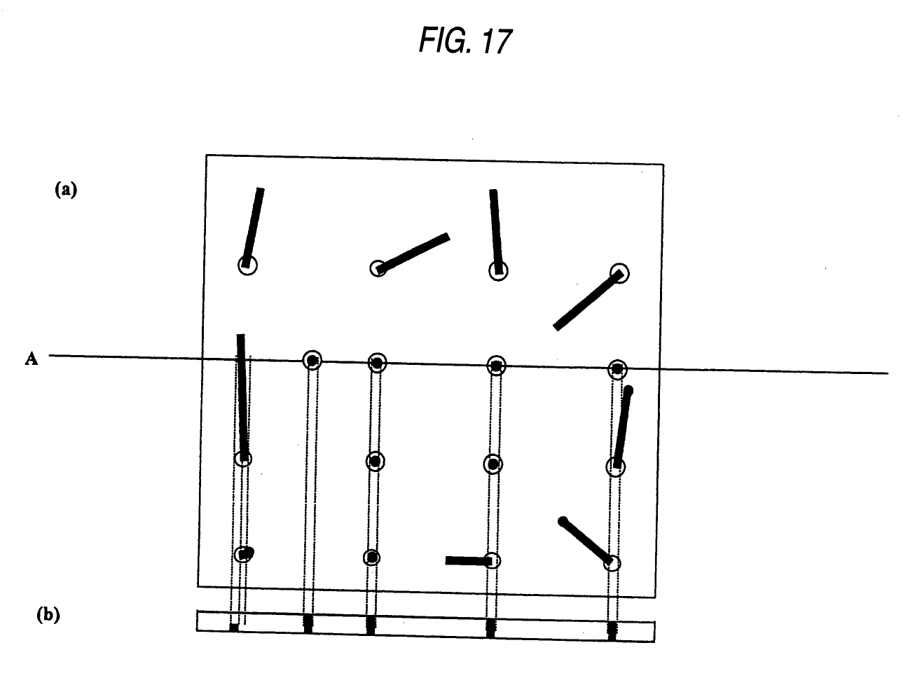

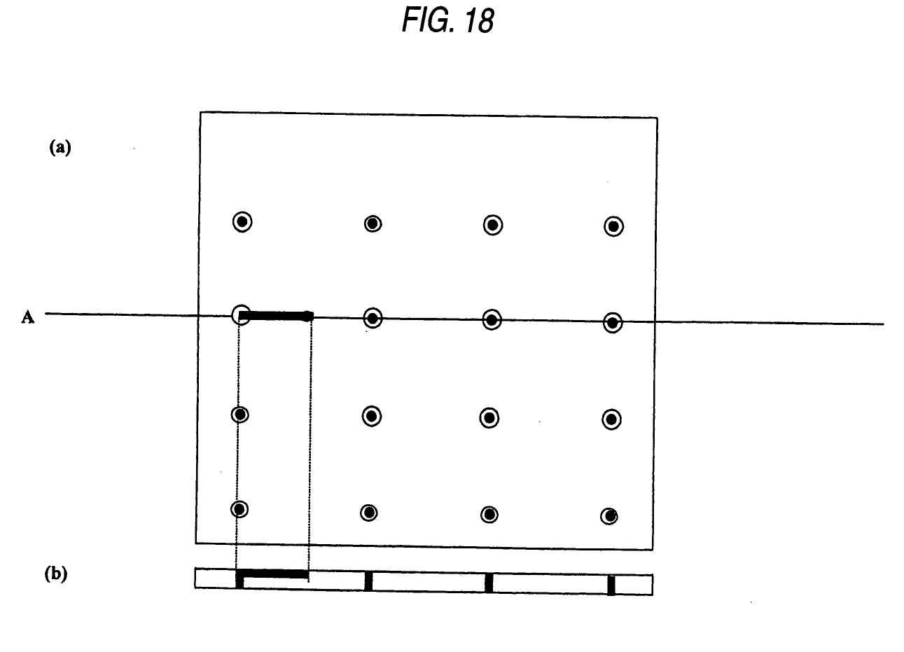

FIGS. 17(a) and 18(b) are respectively a plan view and a sectional view showing the third layer wiring of the semiconductor integrated circuit device.

FIGS. 18(a) and 17(b) are respectively a plan view and a sectional view showing the fourth layer wiring of the semiconductor integrated circuit device.

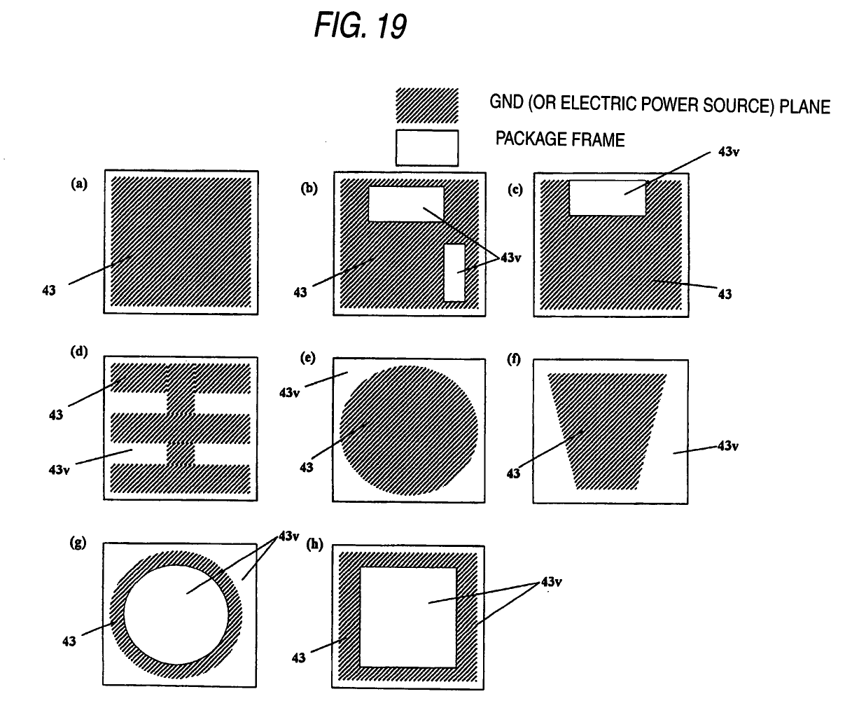

FIGS. 19(a) to 19(h) are plan views showing a variation of the conductive plane.

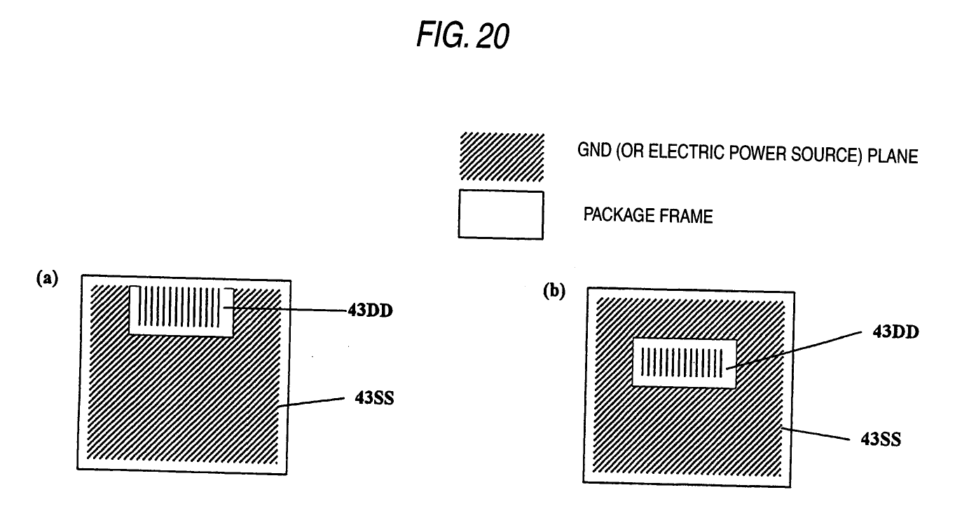

FIGS. 20(a) and 20(b) are plan views showing a variation of the conductive plane.

FIG. 21 is a schematic illustration showing an electrostatic protection circuit of the conventional example.

FIG. 22 is a view showing a semiconductor device in which the electrostatic protection circuit of the conventional example is used.

### DESCRIPTION OF THE PREFERRED EMBODIMENTS

An embodiment of the present invention will be explained as follows.

### FIRST EMBODIMENT

As shown in FIG. 1 which is a sectional view for explaining the structure and also as shown in FIGS. 2 to 9 which are plan views and sectional views showing the semiconductor chip and each layer, the semiconductor integrated circuit device of this embodiment is composed as follows. The semiconductor chip 1 is mounted on the wiring substrate of the multilayer structure having a conductive plane, and the connection to the electrostatic protection circuit 2, which is provided in the semiconductor chip, is made when the electric power source lines are connected in common on the conductive plane 43. The layers are composed in such a manner that when the layers are put on each other, the through-holes coincide with each other and the layers are connected to each other via the through-holes.

As shown in FIG. 1, the device includes: a first to a fourth circuit system which are separately mounted on the semiconductor chip 1 and respectively driven by different electric power source systems; ball grid arrays (BGA) VSS01 to VSS04 having at least one electrostatic protection circuit 2, composing an outer connecting terminal connected to the circuit system of the semiconductor chip via the wiring substrate 4; and a resin package 3 covering the semiconductor chip 1. The signal lines SIG1 to SIG8 of the circuit system of the semiconductor chip, the electric power source lines VDD1 to VDD4 and the ground lines VSS1 to VSS4 are connected in common via the conductive plane 43, which is provided on the wiring substrate 4, so that the signal lines SIG1 to SIG8 of the circuit system of the semiconductor chip, the electric power source lines VDD1 to VDD4 and the ground lines VSS1 to VSS4 can be respectively connected via the electrostatic protection circuit 2. This conductive plane 43 is provided on the substantially entire face of the wiring substrate 4 on which the semiconductor chip is mounted.

The wiring substrate 4 includes: a third layer wiring 41 composed of a copper pattern formed on the surface of the resin board 40; a conductive plane 43, which is a ground plane, formed via the insulating layer 42 composed of a resin layer on an upper layer of the third layer wiring 41; a first layer wiring 45 composed via the insulating layer 44 composed of a polyimide resin layer on an upper layer of the conductive plane 43; an insulating layer 46 composed of a polyimide resin layer which covers an upper layer of the first layer wiring 45; a passivation film 47 composed of a silicon nitride film; a fourth layer wiring 48 formed on the reverse side of the base substrate, connected to VSS01 to VSS04 composing the ball grid arrays; and an insulating layer 49 made of polyimide resin.

On the other hand, as shown in the upper face view of FIG. 2, the semiconductor chip 1 is a silicon chip mounted on the wiring substrate 4 by the flip-chip system. In this view, 16 pieces of the terminals 11 of the semiconductor chip are shown, however, since the silicon chip is actually a flip chip, the terminals 11 can not be seen. FIG. 3 is a view showing a reverse face of the semiconductor chip 1.

Next, this semiconductor chip 1 will be explained below.

First, as shown in FIG. 4, the semiconductor chip 1 includes: input and output cells and electric power source cells (I/O cell region) formed on the surface of the silicon board 1; and an element region (inner circuit region) in which DRAM and an analog circuit are formed, wherein the first layer aluminum wiring is formed so that it can be contacted with the contact formed on the insulating film (not shown) between layers, and further the second layer aluminum wiring is formed via the contact, and further the probing pad 10 for inspection and the pad for the rearrangement (not shown) are formed. In this connection, between the wiring patterns and also between the wiring layers, the insulating film between the layers composed of a silicon nitride film is provided. The input and output cell is provided with an electrostatic protection element 2 composed of a diode.

In this case, a contact hole is formed on the insulating film between the layers so that the probing pads 10 can be exposed, and the probing test can be made by the probe. The probing pads 10 are VDD1, SIG3, SIG4, VSS1, VDD2, SIG5, SIG5, VSS2, VDD3, SIG7, SIG8, VSS3, VDD4, SIG1, SIG2 and VSS4.

On the insulating protection film (not shown) formed on the upper layer, the rearrangement wiring 12 is formed and connected to the solder bumps 11 via the barrier metal as shown in FIG. 5. As described above, the solder bumps are formed on the entire surface of the semiconductor chip. Therefore, the wiring length is short. In this connection, in FIGS. 4 and 5, the fine line shows a wiring layer formed on the semiconductor chip, and the bold line shows a rearrangement wiring 12 formed on the insulating protection film.

As described above, as shown in FIG. 3, concerning the connecting terminals on the semiconductor chip 1, 16 pieces of the solder bumps 11 are arranged on the entire reverse face by the rearrangement wiring.

In this connection, in this semiconductor chip, the probing pads are composed in all terminals of VDD1, SIG3, SIG4, VSS1, VDD2, SIG5, SIG5, VSS2, VDD3, SIG7, SIG8, VSS3, VDD4, SIG1, SIG2 and VSS4. However, when the probing pads are formed only in the input and output circuit in which the probing test is required and the probing pads are not provided in other input and output circuits, the element area can be also reduced without deteriorating the function.

Next, each conductive layers composing the wiring substrate will be explained below.

Referring to FIG. 6, the signal line 45 will be explained. This signal line 45 is connected to the solder bump 11 on the semiconductor chip 1. In this case, the wiring is extended in a direction of spreading on the wiring substrate via the through-hole H1. On the surface of the signal line 45 on the first layer, the semiconductor chip 1 is mounted by the flip chip system. Four solder bumps, which are electric power source lines, located at the center of the semiconductor chip 1 are connected to the conductive plane (the second layer wiring) on the lower layer via the insulating layer 46 covering the signal line 45 on the first layer and via the through-holes H1VSS1 to H1VSS4 penetrating the passivation film 47. These electric power source terminals VSS1 to VSS4 are further connected to BGA of the outer connecting terminals shown in FIG. 10 via the through-holes H3VSS1 to H3VSS4 provided so that the through-holes H3VSS1 to H3VSS4 can penetrate the third layer wiring.

On the other hand, the electric power lines VDD1 to VDD4 located at four corners of the semiconductor chip 1 pass through the third layer wiring via the insulating layer 46 covering the wiring 45 on the first layer, via the through-holes H1VDD1 to H1VDD4 penetrating the passivation film 47 and via the through-holes H2VDD1 to H2VDD4 penetrating the conductive plane (the second layer wiring) on the lower layer. Then, the electric power lines VDD1 to VDD4 are respectively connected to BGA of the outer connecting terminals shown in FIG. 10.

Referring to FIG. 7, the conductive plane 43 of the present invention will be explained below. This conductive plane 43 is formed so that the conductive plane 43 can cover the substantially entire face of the wiring substrate. In this case, the ground lines VSS1 to VSS4 are connected by the contacts C1 to C4 which are shown at the center by the mark x. The other wiring is connected to the third layer wiring 41 located on the lower layer via the through-hole H2 (H2VSS1 to H2VSS4 . . . ) shown by the mark O in the view. In this case, FIG. 7(a) is an upper face view, and FIG. 7(b) is a sectional view taken on line A-A in FIG. 7(a).

Referring to FIG. 8, the third layer wiring 46 of the present invention will be explained below. This third layer wiring 46 is formed so that the third layer wiring 46 can be uniformly spread substantially all over the surface of the semiconductor chip. In this case, FIG. 8(a) is an upper face view, and FIG. 8(b) is a sectional view taken on line A-A in FIG. 8(a). In this case, as shown in FIG. 9, the third layer wiring 46 is connected to the fourth layer wiring 48 via the through-hole H3.

Referring to FIG. 9, the fourth layer wiring 48 of the present invention will be explained below. This fourth layer wiring 43 is formed so that the fourth layer wiring 43 can cover the substantially entire face of the semiconductor chip. In this case, FIG. 9(a) is an upper face view, and FIG. 9(b) is a sectional view taken on line A-A in FIG. 9(a). In this case, as shown in FIG. 10, the fourth layer wiring 48 is formed so that the fourth layer wiring 48 can be connected to BGA5 (the outer connecting terminal), which are uniformly arranged on the reverse face of the wiring substrate, via the through-hole H4.

According to the above constitution, the electrostatic protection circuits 2 are respectively arranged between the signal terminal and the electric power source line or the ground line and between the electric power source line and the ground line, and the connection of the ground line is not located in the semiconductor chip but the connection of the ground line is made on the conductive plane 43. Therefore, the connection can be made at low impedance without causing an increase in the chip area. Accordingly, the operation can be conducted at high speed, and the semiconductor integrated circuit device can be downsized and highly integrated. Further, since the conductive plane for forming the common bus is formed outside the semiconductor integrated circuit chip, no restriction is imposed on the design of the semiconductor integrated circuit chip, and the degree of freedom of designing the semiconductor integrated circuit chip can be enhanced.

### SECOND EMBODIMENT

In this connection, in the above embodiment, the conductive plane 43 formed on the wiring substrate 4 is made to be a ground line. However, in this embodiment, as shown in FIGS. 11, 12(a) and 12(b), in addition to the ground line composed of the conductive plane 43, one layer of the conductive plane 43S and the insulating layer 44S are added, and this conductive plane is made to be an electric power source line. On this conductive plane 43S, the electric power source line is connected via the contacts CD1 to CD4.

Other points of the structure are the same as those of the first embodiment described before.

In this connection, like reference characters are used for like parts in the first and the second embodiment.

In this constitution, not only the ground line but also the electric power source line is comprised of the conductive plane 43. Therefore, it is possible to supply a stable electric potential, and the generation of noise can be reduced.

(Third Embodiment)

In this connection, in the embodiment described before, the conductive plane is connected to one electric potential. However, in this embodiment, as shown in FIGS. 13(a) and 13(b), the conductive plane is divided into two portions, and the electric power source plane 43b is composed in the outside C-shaped region, and the inside region is made to be a ground plane 43a at a predetermined interval. To this ground plane 43a, the ground lines are connected via the contacts C1 to C4. To this electric power source plane 43, the electric power source lines are connected via CD1 to CD4.

Other points of the structure are the same as those of the first embodiment described before.

In this connection, like reference characters are used for like parts in the first and the third embodiment.

In this constitution, the conductive planes of two electric potentials can be composed on one conductive layer without increasing the number of the laminated layers. Therefore, the device can be downsized and the degree of freedom of designing the circuit can be enhanced.

### FOURTH EMBODIMENT

In this connection, in the embodiment described before, the conductive plane is connected to one electric potential. However, in this embodiment, as shown in FIGS. 15, 16(a), 16(b), 17(a), 17(b), 18(a) and 18(b), a ring-shaped conductive layer is formed on the signal line layer.

It is possible to adopt such a structure that a ring-shaped conductive layer is inserted into the third layer wiring of the first embodiment described before and connected in common. Due to the above structure, the inside of the conductive plane can be used as a wiring region for signals. Therefore, the number of layers can be reduced by one, and further the length of the electric power source wiring to be laid round can be easily made constant. FIGS. 16(a), 16(b), 17(a), 17(b), 18(a) and 18(b) respectively show the conductive plane, the third signal line layer and the fourth signal line layer. This embodiment is somewhat different from the first embodiment described before, however, this embodiment is almost similar to the first embodiment.

### FIFTH EMBODIMENT

In this connection, in the first embodiment described before, the conductive plane is formed on the substantially entire surface of the wiring substrate. However, the conductive plane may be formed in one region of the surface of the wiring substrate. FIGS. 19(a) to 19(h) are views of a variation showing a profile of the conductive plane.

FIG. 19(a) is a view showing a state in which the conductive plane is formed on the wiring substrate surface except for the outer circumference. Due to this structure, even when the wiring substrate is mounted without conducting resin sealing on the side of the resin package, there is no possibility that moisture soaks into the substrate from an interface between the conductive plane and the insulating layer, that is, there is no possibility that the elements are deteriorated.

FIG. 19(b) is a view showing a state in which the conductive plane is formed on the wiring substrate surface except for two lacking portions 43v. In the case where through-holes are formed in these portions from the upper layer to the lower layer so as to make the connection, when the through-holes are formed in these lacking portions 43v, it is possible to prevent the occurrence of short circuit. Therefore, the reliability can be enhanced.

FIG. 19(c) is a view showing a state in which the conductive plane is formed on the wiring substrate surface except for the lacking portion 43v located in the periphery. In this embodiment, the same effect as that of the above embodiment can be provided.

FIG. 19(d) is a view showing a state in which the conductive plane is formed on the wiring substrate surface except for the lacking portion 43v which is formed so that the wiring substrate surface can be divided into a plurality of regions, that is, the lacking portion 43v is formed being divided into a plurality of regions. When the wires of the different signal systems are arranged in these regions of the lacking portion 43v, each signal system is separated via the conductive plane. Therefore, it is possible to prevent the occurrence of cross talk. This embodiment provides the same effect as that of the embodiment described before.

FIG. 19(e) is a view showing a state in which the conductive plane is formed in a circular region located at the center of the wiring substrate surface, and the lacking portion 43v is located at the four corners of the wiring substrate. In this embodiment, it is possible to arrange the wiring so that the distance from the chip to the electrically conducive plane can be made equal.

FIG. 19(f) is a view showing a state in which the conductive plane is formed in a trapezoidal region at the center of the wiring substrate surface, and the lacking portion 43v is extended to two regions.

FIG. 19(g) is a view showing a state in which the conductive plane is formed in a ring-shaped region at the center of the wiring substrate surface, and the lacking portion 43v is extended to two regions, and further the connecting distance to the conductive plane is short and uniform.

FIG. 19(h) is a view showing a state in which the conductive plane is formed in a square-ring-shaped region at the center of the wiring substrate surface, and the lacking portion 43v is extended to two regions, and further the connecting distance to the conductive plane is short and uniform.

### SIXTH EMBODIMENT

In this connection, in the third embodiment described before, the electric power source plane and the ground plane are formed on one layer. Examples of dividing the shape are shown in FIGS. 20(a) and 20(b).

The division of the shape can be appropriately changed according to the pattern arrangement.

FIG. 20(a) is a view showing a state in which the ground plane 43SS is formed into a C-shape so that the electric power source plane 43DD can be surrounded by the C-shape.

FIG. 20(b) is a view showing a state in which the ground plane 43SS is formed so that the circumference of the electric power source plane 43DD can be surrounded by the ground plane 43SS.

In this connection, in the above embodiment, explanations are made into the flip-chip package. However, the present invention is not limited to the flip-chip package. The present invention can be applied to a package including wire-bonding.

Of course, this constitution can be applied to the case of a chip size package (CSP) in which the mounting is conducted in the form of a wafer and terminals such as BGA are formed and then dicing is performed.

In this connection, in the case of forming the multilayer wiring substrate described before, the formation can be easily performed by repeating the processes of formation of the conductive pattern on the resin board, patterning by photolithography, formation of the insulating layer and formation of through-holes by photolithography in order.

The multilayer wiring substrate can be also easily formed when the wiring layer pattern is formed on a half-hardened resin board, which is referred to as prepreg, and laminated and hardened.

The multilayer wiring substrate can be also formed when the multilayer wiring is formed and stuck to the semiconductor chip.

Of course, the present invention can be applied to a semiconductor device in which the semiconductor chip is mounted on a film carrier on which a conductor pattern is formed, and copper foil to be used as a conductive plane is interposed and sealed up.

In addition to that, in the above embodiment, the electrostatic protection element is mounted on the semiconductor chip. However, the electrostatic protection element may be integrated with the conductive plane. Due to the foregoing, the chip area can be further reduced.

According to the present invention, the occurrence of noise can be reduced, and the semiconductor device can be downsized and highly integrated. The present invention can be effectively used for mounting a semiconductor device which requires multiple electric potentials. Therefore, the present invention can be applied to LSI on which DRAM, SRAM and an analog circuit are mixedly mounted. Therefore, it becomes possible to compose a small-sized LSI.

1. A semiconductor integrated circuit device comprising:
a semiconductor integrated circuit chip, mounted on a semiconductor base, the semiconductor integrated circuit chip having a plurality of circuit systems mounted being separated and driven by different electric power source systems; and
an outer connecting terminal connected to the circuit systems of the semiconductor integrated circuit chip via a wiring member having at least one wiring layer;
wherein electric power source lines of the plurality of circuit systems of the semiconductor integrated circuit chip are commonly connected on a conductive plane, which is provided in the wiring member, via an electrostatic protection circuit.

2. The semiconductor integrated circuit device according to claim 1, wherein the electrostatic protection circuit is formed in the semiconductor integrated circuit chip.

3. The semiconductor integrated circuit device according to claim 1, wherein the conductive plane is connected to the ground potential.

4. The semiconductor integrated circuit device according to claim 1, wherein the conductive plane is connected to the electric power source potential.

5. The semiconductor integrated circuit device according to claim 1, wherein the conductive plane is divided into a plurality of regions on the same layer and connected being divided into the electric power source potentials which are different from each other for each region.

6. The semiconductor integrated circuit device according to claim 1, wherein the conductive plane is divided into a plurality of regions on the same layer and includes a region connected to the electric power source potential and a region connected to the ground potential.

7. The semiconductor integrated circuit device according to claim 1, wherein the conductive plane includes a plurality of layers of conductive planes formed so that an insulating layer is interposed between the conductive planes, and at least one layer of the conductive planes is connected to the ground potential.

8. The semiconductor integrated circuit device according to claim 1, wherein the conductive plane is provided on the wiring substrate and electrically connected to the semiconductor integrated circuit chip via the through-hole provided on the wiring substrate.

9. The semiconductor integrated circuit device according to claim 1, wherein the conductive plane is formed substantially all over the wiring substrate surface.

10. The semiconductor integrated circuit device according to claim 1, wherein the conductive plane is a conductive ring.

11. The semiconductor integrated circuit device according to claim 1, wherein the conductive plane composes one layer of the multilayer wiring substrate.

12. The semiconductor integrated circuit device according to claim 1, wherein the outer connecting terminal is a terminal for mounting on the surface which is led out onto a lower face of the resin package.

13. The semiconductor integrated circuit device according to claim 12, wherein the outer connecting terminal is a ball grid array.

14. The semiconductor integrated circuit device according to claim 12, wherein the outer connecting terminal is a pin grid array.

15. The semiconductor integrated circuit device according to claim 1, wherein the semiconductor integrated circuit device is of the CPS type.

16. The semiconductor integrated circuit device according to claim 1, wherein the electrostatic protection circuit is arranged on the wiring member.

17. The semiconductor integrated circuit device according to claim 1, wherein the electrostatic protection circuit is composed of parts of the chip mounted on the conductive plane.
